(19) United States
(12) Patent Application Publication
(10) Pub. No.: US 2022/0121641 A1
(43) Pub. Date: Apr. 21, 2022

(54) MULTI-SENSOR-BASED STATE ESTIMATION METHOD AND APPARATUS AND TERMINAL DEVICE

(71) Applicant: SUTENG INNOVATION TECHNOLOGY CO., LTD., Shenzhen (CN)

(72) Inventor: Yufan FANG, Shenzhen (CN)

(73) Assignee: SUTENG INNOVATION TECHNOLOGY CO., LTD., Shenzhen (CN)

(21) Appl. No.: 17/566,749

(22) Filed: Dec. 31, 2021

Related U.S. Application Data
(63) Continuation of application No. PCT/CN2019/094491, filed on Jul. 3, 2019.

(51) Int. Cl. G06F 16/23; H03H 17/02

(52) U.S. Cl. CPC G06F 16/23; H03H 17/0257

(57) ABSTRACT

This application provides a multi-sensor-based state estimation method, an apparatus, and a terminal device. The method includes: in each cycle, extracting sensor messages and arranging the sensor messages into a queue; deleting a system state estimation value with a timestamp later than an initial timestamp; extracting the sensor messages from the queue; when prediction data is extracted, predicting a system state estimation value corresponding to the first timestamp according to a Kalman filter prediction algorithm; when the update data is extracted, obtaining the system state estimation value corresponding to the first timestamp, and updating the system state estimation value according to a Kalman filter update algorithm; after all the sensor messages in the queue are used, proceed to a next cycle; and detecting a system state estimation value with the latest timestamp in the state estimation queue, and outputting the system state estimation value.

### CROSS-REFERENCE TO RELATED APPLICATION

The present application is a continuation of International Application No. PCT/CN2019/094491, filed on Jul. 3, 2019, which is incorporated herein by reference in its entirety.

### TECHNICAL FIELD

This application relates to the field of data processing technologies, and in particular, to a multi-sensor-based state estimation method, an apparatus, and a terminal device.

### BACKGROUND

As a key technology in the field of positioning and navigation for robots and autonomous driving, state estimation refers to a process of estimating a current value or historical value of a state variable of a system through measurement information from one or more sensors with reference to a mathematical model of the system. Main state variables of the system can be information of a robot or a vehicle such as current position, posture, linear velocity, angular velocity, etc.

During state estimation, compared with single-sensor measurement, multi-sensor redundant measurement of the system can implement more accurate state estimation. An existing mainstream solution to multi-sensor redundant measurement is fusion of multi-sensor information based on a Kalman filter.

However, when the existing Kalman filter is used to fuse the multi-sensor information, time needs to be synchronized, and in this case, some measurement data may be lost, time synchronization is difficult, and the Kalman filter has a low output frequency, making it difficult to meet the system's requirements for high dynamic performance and real-time performance.

### SUMMARY

In view of this, embodiments of this application provide a multi-sensor-based state estimation method, an apparatus, and a terminal device to resolve the following problem: When the existing Kalman filter is used to fuse the multi-sensor information, time needs to be synchronized, and in this case, some measurement data may be lost, time synchronization is difficult, and the Kalman filter has a low output frequency, making it difficult to meet the system's requirements for high dynamic performance and real-time performance.

According to a first aspect of embodiments of this application, a multi-sensor-based state estimation method is provided, including:

in each state estimation cycle, using an earliest timestamp among timestamps of one or more unused sensor messages in one or more sensor message queues as an initial timestamp, extracting, from the one or more sensor message queues, one or more sensor messages whose timestamps are later than or equal to the initial timestamp, and arranging the one or more sensor messages into a data update queue according to a sequence of timestamps, wherein a sensor message queue is used to receive a sensor message collected by a sensor participating in state estimation;

deleting a system state estimation value with a timestamp later than the initial timestamp from a state estimation queue, wherein the state estimation queue is used to store a system state estimation value predicted or updated according to the sensor message;

sequentially extracting the one or more sensor messages from the data update queue, wherein the one or more sensor messages include prediction data and update data; and using a timestamp of one of the extracted one or more sensor messages as a first timestamp;

when an extracted sensor message is prediction data, according to a Kalman filter prediction algorithm, predicting a system state estimation value corresponding to the first timestamp by using a last system state estimation value in the state estimation queue and the extracted sensor message;

when an extracted sensor message is update data, obtaining a system state estimation value corresponding to the first timestamp, and updating the system state estimation value corresponding to the first timestamp by using the extracted sensor message according to a Kalman filter update algorithm to obtain a new system state estimation value corresponding to the first timestamp;

after all of the one or more sensor messages in the data update queue are used to predict or update the system state estimation value in the state estimation queue, proceeding to a next state estimation cycle; and

detecting a system state estimation value with the latest timestamp in the state estimation queue at a predetermined frequency, and outputting the detected system state estimation value.

According to a second aspect of the embodiments of this application, a multi-sensor-based state estimation apparatus is provided, including:

a queue update module, configured to, in each state estimation cycle, use an earliest timestamp among timestamps of one or more unused sensor messages in one or more sensor message queues as an initial timestamp, to extract, from the one or more sensor message queues, one or more sensor messages whose timestamps are later than or equal to the initial timestamp, and to arrange the one or more sensor messages into a data update queue according to a sequence of timestamps, wherein a sensor message queue is used to receive a sensor message collected by a sensor participating in state estimation;

a state deletion module, configured to delete a system state estimation value with a timestamp later than the initial timestamp from a state estimation queue, wherein the state estimation queue is used to store a system state estimation value predicted or updated according to the sensor message;

a data extraction module, configured to sequentially extract the one or more sensor messages from the data update queue, wherein the one or more sensor messages include prediction data and update data, and to use a timestamp of one of the extracted one or more sensor messages as a first timestamp;

a state prediction module, configured to, when an extracted sensor message is prediction data, according to a Kalman filter prediction algorithm, predict a system state estimation value corresponding to the first timestamp by using a last system state estimation value in the state estimation queue and the extracted sensor message;

a state update module, configured to, when an extracted sensor message is update data, obtain a system state estimation value corresponding to the first timestamp, and to update the system state estimation value corresponding to the first timestamp by using the extracted sensor message according to a Kalman filter update algorithm to obtain a new system state estimation value corresponding to the first timestamp;

a state cycling module, configured to, after all of the one or more sensor messages in the data update queue are used to predict or update the system state estimation value in the state estimation queue, proceed to a next state estimation cycle; and

a state output module, configured to detect a system state estimation value with the latest timestamp in the state estimation queue at a predetermined frequency, and to output the detected system state estimation value.

According to a third aspect of the embodiments of this application, a terminal device is provided, including a memory, a processor, and a computer program stored in the memory and capable of running on the processor, where when the processor executes the computer program, steps of the foregoing method are implemented.

According to a fourth aspect of the embodiments of this application, a computer-readable storage medium is provided, where the computer-readable storage medium stores a computer program, and when the computer program is executed by a processor, steps of the foregoing method are implemented.

In the multi-sensor-based state estimation method in this application, during Kalman filtering, time does not need to be synchronized, all received sensor messages are used to perform state estimation, and predict or update the corresponding system state estimation value, which can avoid losing data measured by sensors, thereby obtaining a more accurate system state estimation value. In addition, because time does not need to be synchronized, in a Kalman filtering cycle, a cycling period does not need to be synchronized with that of a sensor with the lowest measurement frequency, an output frequency for the state estimation can be randomly selected, and even reach the same output frequency as a sensor with the highest measurement frequency, which greatly improves the real-time performance of the algorithm and can satisfy the system's requirements for high dynamic performance and real-time performance, thereby resolving the following problem: When the existing Kalman filter is used to fuse the multi-sensor information, time needs to be synchronized, and in this case, some measurement data may be lost, time is difficult to synchronize, and the Kalman filter has a low output frequency, making it difficult to meet the system's requirements for high dynamic performance and real-time performance.

### BRIEF DESCRIPTION OF THE DRAWINGS

To describe the technical solutions in the embodiments of this application more clearly, the following briefly introduces the accompanying drawings for describing the embodiments. Apparently, the accompanying drawings in the following description show merely some embodiments of this application, and a person of ordinary skill in the art may derive other drawings from these accompanying drawings without creative efforts.

FIG. 1 is a schematic diagram of an implementation procedure of a multi-sensor-based state estimation method according to an embodiment of this application.

FIG. 2 is a schematic diagram of a multi-sensor-based state estimation apparatus according to an embodiment of this application.

FIG. 3 is a schematic diagram of a terminal device according to an embodiment of this application.

FIG. 4 is a schematic diagram of updating a state estimation queue according to an embodiment of this application.

### DETAILED DESCRIPTION

For the purpose of illustration rather than limitation, the following describes specific details such as a specific system structure and technology, to facilitate a thorough understanding of the embodiments of this application. However, a person skilled in the art should understand that this application can also be implemented in other embodiments without these details. In other cases, detailed descriptions of well-known systems, apparatuses, circuits, and methods are omitted, to prevent unnecessary details from causing distraction from the description of this application.

To illustrate the technical solution in this application, specific embodiments are provided below.

It should be understood that when used in this specification and appended claims, a term “include” indicates existence of a described feature, integrity, a step, an operation, an element and/or a component, but does not exclude existence or addition of one or more other features, integrity, steps, operations, elements, components and/or a collection thereof.

It should also be understood that the terms used in the specification of this application are only used to describe the specific embodiments and are not intended to limit this application. As used in the specification and the appended claims of this application, unless otherwise the context clearly indicates another case, singular forms of “a,” “an” and “the” are intended to include plural forms.

It should be further understood that the term “and/or” used in the specification and the appended claims of this application refers to any combination of one or more of the associated items listed and all possible combinations thereof, and inclusion of these combinations.

As used in the specification and the appended claims, depending on the context, the term “if” can be interpreted as “when,” “once,” “in response to determination,” or “in response to detection.” Similarly, depending on the context, the phrase “if determined” or “if (a described condition or event is) detected” can be interpreted as “once determined,” “in response to determination,” “once (the described condition or event is) detected,” or “in response to detection (of the described condition or event).”

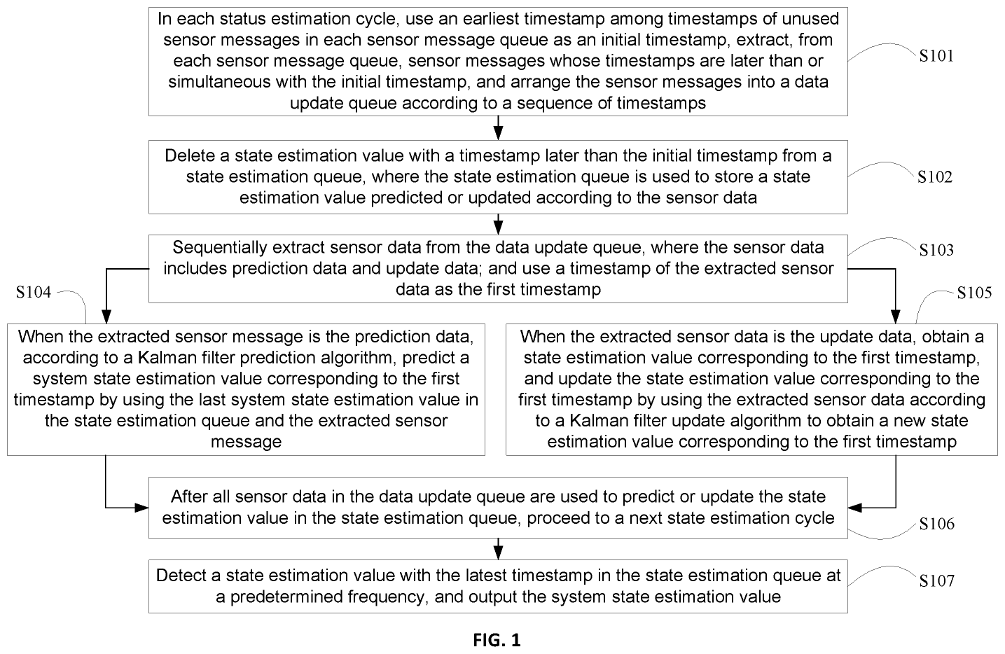

The following describes a multi-sensor-based state estimation method provided in an embodiment of this application. Referring to FIG. 1, the multi-sensor-based state estimation method in this embodiment of this application includes the following steps.

Step S101: In each state estimation cycle, use an earliest timestamp among timestamps of unused sensor messages in each sensor message queue as an initial timestamp, extract, from each sensor message queue, sensor messages whose timestamps are later than or equal to the initial timestamp, and arrange the sensor messages into a data update queue according to a sequence of timestamps, where a sensor message queue is used to receive a sensor message collected by a sensor participating in state estimation.

In each state estimation cycle, a sensor message with the earliest timestamp in the unused sensor messages currently received in each sensor message queue is detected, and the timestamp of the sensor message is used as the initial timestamp.

Then, all the sensor messages whose timestamps are later than or equal to the initial timestamp may be extracted from each sensor message queue, and the sensor messages may be arranged into a sequence according to the sequence of timestamps to obtain the data update queue. For example, sensor messages in a data update queue in the last cycle are {A1, B1, A2, A3}. In this state estimation cycle, if it is detected that a timestamp of newly received sensor data C1 is earlier than that of A1, a data update queue of this cycle may be {C1, A1, B1, A2, A3, B2}, and C1 and B2 are newly received sensor messages. Although A1, B1, A2, and A3 were used in the last cycle, timestamps of A1, B1, A2, and A3 are all later than a timestamp of C1, and therefore, the sensor messages are extracted and reused in this cycle.

The sensor message queue is used to receive the sensor message collected by the sensor participating in the state estimation.

Step S102: Delete a system state estimation value with a timestamp later than the initial timestamp from a state estimation queue, where the state estimation queue is used to store a system state estimation value predicted or updated according to the sensor message.

The state estimation queue is used to store the system state estimation value predicted or updated according to the sensor message. A timestamp of each system state estimation value is the same as a timestamp of a sensor message used to predict or update the system state estimation value. In each state estimation cycle, after the initial timestamp is obtained, the system state estimation value with the timestamp later than the initial timestamp is deleted from the state estimation queue. For example, the state estimation queue may be denoted as {K1, K2, K3, K4, K5, K6}. Herein, timestamps of K3 to K6 are all later than the initial timestamp, and in this case, system state estimation values of K3 to K6 can be deleted. Then the system state estimation value is predicted or updated according to the data update queue in this state estimation cycle.

Step S103: Sequentially extract sensor messages from the data update queue, where the sensor messages include prediction data and update data; and use a timestamp of one of the extracted sensor messages as a first timestamp.

After invalid system state estimation values are deleted from the state estimation queue, the sensor messages can be extracted from the data update queue sequentially, the system state estimation value is predicted or updated according to the extracted sensor messages, and the sensor messages include prediction data and update data. For example, one sensor can be selected as a prediction sensor, a sensor message detected by this sensor is prediction data, another sensor is used as an update sensor, and the sensor message detected by the another sensor is update data. When the sensor message is extracted, a timestamp of the currently extracted sensor message is used as the first timestamp.

Sensors participating in state estimation include the update sensor and the prediction sensor. Usually, only one prediction sensor is provided and one or more update sensors can be provided. A sensor message collected by prediction sensor is prediction data, and a sensor message collected by update sensors is update data.

Step S104: When the extracted sensor message is prediction data, according to a Kalman filter prediction algorithm, predict a system state estimation value corresponding to the first timestamp by using the last system state estimation value in the state estimation queue and the extracted sensor message.

When the extracted sensor message is prediction data, according to the Kalman filter prediction algorithm, the system state estimation value corresponding to the first timestamp can be predicted based on the last system state estimation value in the state estimation queue and the extracted sensor message, and the predicted system state estimation value becomes the new last system state estimation value in the state estimation queue.

Kalman filter algorithms include a prediction algorithm and an update algorithm. Through the prediction algorithm and the update algorithm, state estimation can be performed by using a status equation and a detection equation for the system.

Step S105: When the extracted sensor message is update data, obtain a system state estimation value corresponding to the first timestamp, and update the system state estimation value corresponding to the first timestamp by using the extracted sensor message according to the Kalman filter update algorithm to obtain a new system state estimation value corresponding to the first timestamp.

When the extracted sensor message is update data, the system state estimation value corresponding to the first timestamp is obtained, and then the system state estimation value corresponding to the first timestamp is updated by using the extracted sensor message according to the Kalman filter update algorithm to obtain the new system state estimation value. The new system state estimation value so updated becomes the new last system state estimation value in the state estimation queue.

Step S106: After all sensor messages in the data update queue are used to predict or update the system state estimation value in the state estimation queue, proceed to a next state estimation cycle.

The sensor messages are extracted from the data update queue sequentially to predict or update the system state estimation value in the state estimation queue. After all the sensor messages in the data update queue are used, the next state estimation cycle is started.

Step S107: Detect a system state estimation value with the latest timestamp in the state estimation queue at a predetermined frequency, and output the system state estimation value.

When the system state estimation value needs to be output, the state estimation queue can be scanned at a predetermined frequency to detect a system state estimation value with the latest timestamp in the current state estimation queue, that is, the last system state estimation value in the state estimation queue, and output the system state estimation value after detection.

The predetermined frequency is set according to an actual need. For example, if high real-time performance is required, the predetermined frequency can be set to be the same as the detection frequency of the sensor with the highest detection frequency. If high real-time performance is not required, the predetermined frequency can be set as a lower frequency. A specific setting scheme can be selected according to the actual need.

A process of outputting the system state estimation value and a process of the state estimation cycle can be synchronous processes or asynchronous processes. The same frequency or different frequencies can be used in the two processes. For example, for the state estimation cycle, the frequency of the sensor with the highest detection frequency can be used as the cycle frequency. The predetermined frequency can be the same as or different from the cycle frequency. The system state estimation value with the latest timestamp after each state estimation cycle can be selected for output, or the system state estimation value with the latest timestamp after multiple state estimation cycles can also be output.

Further, when the extracted sensor message is update data, obtaining a system state estimation value corresponding to the first timestamp, and updating the system state estimation value corresponding to the first timestamp by using the extracted sensor message according to the Kalman filter update algorithm to obtain a new system state estimation value corresponding to the first timestamp specifically include the following steps:

A1. When the extracted sensor message is update data, determine whether there is a system state estimation value corresponding to the first timestamp.

When the extracted sensor message is update data, it may be first determined whether there is a system state estimation value corresponding to the first timestamp. During actual application, when a difference between a timestamp of the system state estimation value and the first timestamp is less than a predetermined time threshold, it can be determined that the system state estimation value is the system state estimation value corresponding to the first timestamp. The predetermined time threshold can be set based on a precision requirement in an actual application process and engineering experience.

A2. When there is a system state estimation value corresponding to the first timestamp, update the system state estimation value corresponding to the first timestamp by using the extracted sensor message according to the Kalman filter update algorithm to obtain a new system state estimation value corresponding to the first timestamp.

If there is a system state estimation value corresponding to the first timestamp, the system state estimation value corresponding to the first timestamp may be directly updated by using the extracted sensor message according to the Kalman filter update algorithm to obtain the new system state estimation value corresponding to the first timestamp.

Further, when the extracted sensor message is update data, obtaining a system state estimation value corresponding to the first timestamp, and updating the system state estimation value corresponding to the first timestamp by using the extracted sensor message according to the Kalman filter update algorithm to obtain a new system state estimation value corresponding to the first timestamp further include the following step:

A3. When there is no system state estimation value corresponding to the first timestamp, perform interpolation calculation according to the last system state estimation value in the state estimation queue to obtain the system state estimation value corresponding to the first timestamp, and update the system state estimation value corresponding to the first timestamp by using the sensor message according to the Kalman filter update algorithm to obtain the new system state estimation value corresponding to the first timestamp.

When there is no system state estimation value corresponding to the first timestamp, interpolation calculation can be performed according to the last system state estimation value in the state estimation queue, to obtain the system state estimation value corresponding to the first timestamp based on a kinematics equation for the system through linear interpolation and the like, and then the system state estimation value corresponding to the first timestamp is updated by using the sensor message according to the Kalman filter update algorithm to obtain the new system state estimation value. The new updated system state estimation value becomes the new last system state estimation value in the state estimation queue.

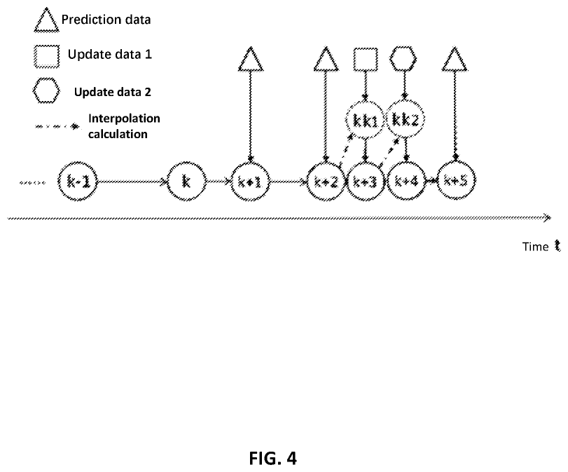

Using FIG. 4 as an example, there are 3 pieces of prediction data and 2 pieces of update data in the data update queue. When the first sensor message is prediction data, a system state estimation value k+1 is predicted based on the system state estimation value k and the first prediction data; the second data is still prediction data, and a system state estimation value k+2 is predicted based on the system state estimation value k+1 and the second prediction data; the third data is update data, then interpolation calculation is performed according to the system state estimation value k+2, to obtain a system state estimation value kk1, and then kk1 is updated by using the update data 1, to obtain a system state estimation value k+3; the fourth data is update data, interpolation calculation is performed according to the system state estimation value k+3, to obtain a system state estimation value kk2, and kk2 is updated by using the update data 2 to obtain a system state estimation value k+4; and the fifth data is prediction data, a system state estimation value k+5 is predicted according to the system state estimation value k+4 and the third prediction data.

Further, the method further includes the following step:

B1. Delete a sensor message whose retention duration is greater than a predetermined duration.

The retention duration of a sensor message is time interval between the timestamp of the sensor message and the current timestamp, which indicates the time in which the sensor message has been retained. When the retention duration of the sensor message stored in the system is greater than the predetermined duration, the sensor message can be determined as expired data. To save the storage space of the system, the expired data can be deleted. The predetermined duration can be set according to an actual need. For example, the predetermined duration can be set to 5 minutes, 10 minutes, or the like.

Further, in each state estimation cycle, prior to the performance of using an earliest timestamp in timestamps of unused sensor messages in each sensor message queue as an initial timestamp, extracting, from each sensor message queue, sensor messages whose timestamps are later than or equal to the initial timestamp, and arranging the sensor messages into a data update queue according to a sequence of timestamps, where the sensor message queue is used to receive a sensor message collected by a sensor participating in state estimation, the method further includes the following step:

C1. Set a predetermined number of sensor message queues, and receive a sensor message from a corresponding sensor by using the sensor message queue, where the predetermined number is the number of sensors participating in Kalman filtering, and one sensor message queue corresponds to one sensor participating in Kalman filtering.

When data measured by a sensor is received, a predetermined number of sensor message queues can be set. The predetermined number is the number of sensors participating in Kalman filtering. Each sensor corresponds to a sensor message queue, to avoid confusion of timestamps of different sensors in the sensor message queue. For example, detected data of the sensor A is processed faster than detected data of the sensor B, and it is possible that the sensor A's sensor message with a timestamp of 30′17″ is completely processed and arranged into the sensor message queue at 30′31″, and the sensor B's sensor message with a timestamp of 30′03″ is not arranged into the sensor message queue until 30′35″. If a single queue is used, it is inconvenient to detect the sensor message with the earliest timestamp in the unused sensor messages, and timestamps of newly received sensor messages need to be detected sequentially. For example, if the newly received sensor messages are {A1, B1, A2, B2, C1}, timestamps of the newly received sensor messages need to be detected sequentially. When one sensor corresponds to a sensor message queue, received sensor messages in each sensor message queue must be arranged in a sequence of timestamps. In this case, by using only the earliest sensor message in the newly received sensor messages in each sensor message queue, the sensor message with the earliest timestamp in the unused sensor messages can be detected. For example, the newly received sensor messages in the sensor message queues are {A1, A2}, {B31}, and {C1, C2}, and a sensor message with the earliest timestamp in the unused sensor messages can be obtained by comparing only timestamps of A1, B1, and C1.

When the sensor message is received by using the sensor message queue, a process of receiving the sensor message and a process of a state estimation cycle are asynchronous processes. During the state estimation cycle, the sensor message queue is still continuously used to receive sensor messages and new received sensor messages are used in the next state estimation cycle.

In the multi-sensor-based state estimation method in this embodiment, during Kalman filtering, time does not need to be synchronized, all received sensor messages are used to perform state estimation and to predict or update the corresponding system state estimation value, which can avoid losing data measured by sensors, thereby obtaining a more accurate system state estimation value. In addition, because time does not need to be synchronized, in a Kalman filtering cycle, a cycling period does not need to be synchronized with that of a sensor with the lowest measurement frequency, and an output frequency for the state estimation can be freely selected and even reach the same output frequency as a sensor with the highest measurement frequency, which greatly improves the real-time performance of the algorithm and can satisfy the system's requirements for high dynamic performance and real-time performance, thereby resolving the following problem: When the existing Kalman filter is used to fuse multi-sensor information, time needs to be synchronized, and in this case, some measurement data may be lost, time is difficult to synchronize, and the Kalman filter has a low output frequency, making it difficult to meet the system's requirements for high dynamic performance and real-time performance.

When the system state estimation value is updated by using update data, it can be first detected whether there is a system state estimation value corresponding to the first timestamp. If yes, the system state estimation value is updated by using the sensor message according to the Kalman filter update algorithm; or if no, the system state estimation value corresponding to the first timestamp is obtained through interpolation calculation. Then the system state estimation value is updated.

When the timestamp of a sensor is too early, the sensor message can be determined as expired data, and the expired data is deleted to save storage space.

To receive sensor messages, multiple sensor message queues can be used, and each sensor message queue corresponds to one sensor, to orderly receive the sensor messages, thereby improving efficiency of processing and invoking data.

It should be understood that a sequence number of each step in the foregoing embodiments does not mean an execution sequence. An execution sequence of each process should be determined based on a function and internal logic of each process, and should not constitute any limitation to an implementation process of the embodiments of this application.

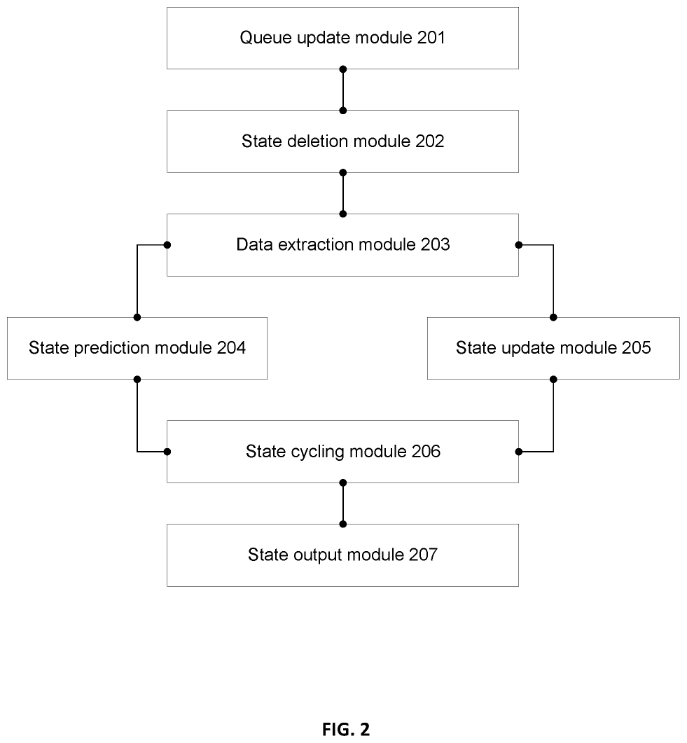

An embodiment of this application provides a multi-sensor-based state estimation apparatus. For ease of description, only parts related to this application are shown. As shown in FIG. 2, the multi-sensor-based state estimation apparatus includes:

a queue update module 201, configured to, in each state estimation cycle, use an earliest timestamp among timestamps of unused sensor messages in each sensor message queue as an initial timestamp, to extract, from each sensor message queue, sensor messages whose timestamps are later than or equal to the initial timestamp, and to arrange the sensor messages into a data update queue according to a sequence of timestamps, where the sensor message queue is used to receive a sensor message collected by a sensor participating in state estimation;

a state deletion module 202, configured to delete a system state estimation value with a timestamp later than the initial timestamp from a state estimation queue, where the state estimation queue is used to store a system state estimation value predicted or updated according to a sensor message;

a data extraction module 203, configured to sequentially extract sensor messages from the data update queue, where the sensor messages include prediction data and update data; and to use a timestamp of one of the extracted sensor messages as a first timestamp;

a state prediction module 204, configured to, when the extracted sensor message is prediction data, according to a Kalman filter prediction algorithm, predict a system state estimation value corresponding to the first timestamp by using the last system state estimation value in the state estimation queue and the extracted sensor message;

a state update module 205, configured to, when the extracted sensor message is the update data, obtain a system state estimation value corresponding to the first timestamp, and to update the system state estimation value corresponding to the first timestamp by using the extracted sensor message according to the Kalman filter update algorithm to obtain a new system state estimation value corresponding to the first timestamp;

a state cycling module 206, configured to, after all sensor messages in the data update queue are used to predict or update the system state estimation value in the state estimation queue, proceed to a next state estimation cycle; and

a state output module 207, configured to detect a system state estimation value with the latest timestamp in the state estimation queue at a predetermined frequency, and to output the system state estimation value.

Further, the state update module 206 specifically includes:

a state determining submodule, configured to, when the extracted sensor message is update data, determine whether there is a system state estimation value corresponding to the first timestamp;

a first update submodule, configured to, when there is a system state estimation value corresponding to the first timestamp, update the system state estimation value corresponding to the first timestamp by using the sensor message according to the Kalman filter update algorithm to obtain a new system state estimation value corresponding to the first timestamp.

Further, the state update module 206 further includes:

a second update submodule, configured to, when there is no system state estimation value corresponding to the first timestamp, perform interpolation calculation according to the last system state estimation value in the state estimation queue to obtain the system state estimation value corresponding to the first timestamp, and to update the system state estimation value corresponding to the first timestamp by using the sensor message according to the Kalman filter update algorithm to obtain the new system state estimation value corresponding to the first timestamp.

The apparatus further includes:

an expiry-based deletion module, configured to delete a sensor message whose retention duration is greater than a predetermined duration.

The apparatus further includes:

a sensor-based queuing module, configured to set a predetermined number of sensor message queues, where the predetermined number is the number of sensors participating in Kalman filtering, and one sensor message queue corresponds to one sensor participating in Kalman filtering.

Further, sensors participating in state estimation include an update sensor and a prediction sensor.

It should be noted that content such as information exchange and an execution process between the foregoing apparatuses or units is based on the same concept as the method embodiments of this application. For specific functions and technical effects thereof, reference may be made to the method embodiments. Details are not described herein again.

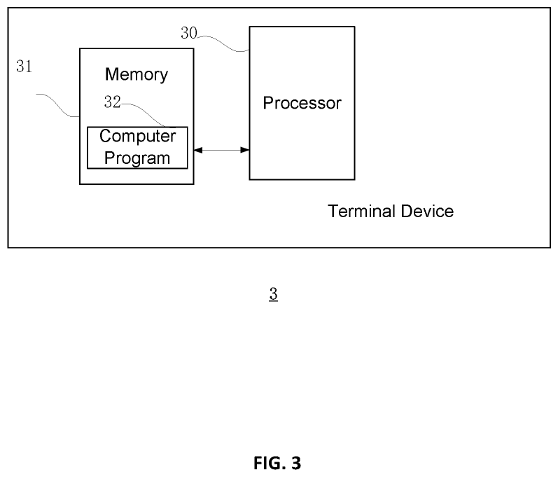

FIG. 3 is a schematic diagram of a terminal device according to an embodiment of this application. As shown in FIG. 3, a terminal device 3 in this embodiment includes a processor 30, a memory 31, and a computer program 32 stored in the memory 31 and capable of running on the processor 30. When the processor 30 executes the computer program 32, steps in the embodiments of the multi-sensor-based state estimation method, such as steps S101 to S107 shown in FIG. 1, are implemented. Alternatively, when the processor 30 executes the computer program 32, the functions of the modules/units in the foregoing apparatus embodiments, such as the functions of the modules 201 to 207 shown in FIG. 2, are implemented.

For example, the computer program 32 may be divided into one or more modules or units, and the one or more modules or units are stored in the memory 31 and are performed by the processor 30 to complete this application. The one or more modules or units may be a series of computer program instruction segments capable of completing specific functions, and the instruction segments are used to describe an execution process of the computer program 32 in the terminal device 3. For example, the computer program 32 may be divided into a queue update module, a state deletion module, a data extraction module, a state prediction module, a state update module, a state cycling module, and a state output module. Functions of the modules are as follows:

a queue update module, configured to, in each state estimation cycle, use an earliest timestamp in timestamps of unused sensor messages in each sensor message queue as an initial timestamp, to extract, from each sensor message queue, sensor messages whose timestamps are later than or equal to the initial timestamp, and to arrange the sensor messages into a data update queue according to a sequence of timestamps, where the sensor message queue is used to receive a sensor message collected by a sensor participating in state estimation;

a state deletion module, configured to delete a system state estimation value with a timestamp later than the initial timestamp from a state estimation queue, where the state estimation queue is used to store a system state estimation value predicted or updated according to the sensor message;

a data extraction module, configured to sequentially extract sensor messages from the data update queue, where the sensor messages include prediction data and update data; and to use a timestamp of one of the extracted sensor messages as a first timestamp;

a state prediction module, configured to, when the extracted sensor message is prediction data, according to a Kalman filter prediction algorithm, predict a system state estimation value corresponding to the first timestamp by using the last system state estimation value in the state estimation queue and the extracted sensor message;

a state update module, configured to, when the extracted sensor message is update data, obtain a system state estimation value corresponding to the first timestamp, and to update the system state estimation value corresponding to the first timestamp by using the extracted sensor message according to the Kalman filter update algorithm to obtain a new system state estimation value corresponding to the first timestamp;

a state cycling module, configured to, after all sensor messages in the data update queue are used to predict or update the system state estimation value in the state estimation queue, proceed to a next state estimation cycle; and

a state output module, configured to, detect a system state estimation value with the latest timestamp in the state estimation queue at a predetermined frequency, and to output the system state estimation value.

The terminal device 3 may be a computing device such as a desktop computer, a notebook, a palmtop computer, and a cloud server. The terminal device may include, but is not limited to, the processor 30 and the memory 31. A person skilled in the art can understand that FIG. 3 is only an example of the terminal device 3, and does not constitute a limitation to the terminal device 3. The terminal device 3 may include more or fewer components than those shown in the figure, or a combination of some components, or different components. For example, the terminal device 3 may also include input and output devices, a network access device, a bus, or the like.

The processor 30 may be a central processing unit (CPU), or may be another general-purpose processor, a digital signal processor (DSP), an application specific integrated circuit (ASIC), a field-programmable gate array (FPGA) or another programmable logic device, a discrete gate or transistor logic device, a discrete hardware component, or the like. The general-purpose processor may be a microprocessor, or the processor may be any conventional processor or the like.

The memory 31 may be an internal storage unit of the terminal device 3, such as a hard disk or a memory of the terminal device 3. The memory 31 may alternatively be an external storage device of the terminal device 3, for example, a plug-connected hard disk, a smart media card (Smart Media Card, SMC), a secure digital (Secure Digital, SD) card, or a flash card (Flash Card) equipped on the terminal device 3. Further, the memory 31 may alternatively include both the internal storage unit and the external storage device of the terminal device 3. The memory 31 is configured to store the computer program and other programs and data required by the terminal device. The memory 31 can also be configured to temporarily store output data or to-be-output data.

A person skilled in the art can clearly understand that, for the purpose of convenient and brief description, division of the foregoing functional units and modules is taken as an example for illustration. In actual application, the foregoing functions can be allocated to different units and modules and implemented according to a requirement, that is, an inner structure of an apparatus is divided into different functional units and modules to implement all or part of the functions described above. The functional units and modules in the embodiments may be integrated into one processing unit, or each unit may exist alone physically, or two or more units may be integrated into one unit. The integrated unit may be implemented in a form of hardware, or may be implemented in a form of a software functional unit. In addition, specific names of the functional units and modules are only for the convenience of distinguishing one another, and are not intended to limit the protection scope of this application. For a detailed working process of units and modules in the foregoing system, reference may be made to a corresponding process in the foregoing method embodiments. Details are not described again herein.

In the foregoing embodiments, the descriptions of the embodiments have respective focuses. For a part that is not described in detail in one embodiment, reference may be made to related descriptions in other embodiments.

A person of ordinary skill in the art may be aware that the units and algorithm steps in the examples described with reference to the embodiments disclosed in this specification can be implemented by electronic hardware or a combination of computer software and electronic hardware. Whether the functions are performed by hardware or software depends on particular applications and design constraints of the technical solutions. A person skilled in the art may use different methods to implement the described functions for each particular application, but it should not be considered that the implementation goes beyond the scope of this application.

In the embodiments provided in this application, it should be understood that the disclosed apparatus, terminal device, and method may be implemented in other manners. For example, the embodiments of the described apparatus or terminal device are merely examples. For example, the module or unit division is merely logical function division and may be other division in actual implementation. For example, a plurality of units or components may be combined or integrated into another system, or some features may be ignored or not performed. In addition, the displayed or discussed mutual couplings or direct couplings or communication connections may be implemented by using some interfaces. The indirect couplings or communication connections between the apparatuses or units may be implemented in electronic, mechanical, or other forms.

The units described as separate parts may or may not be physically separate, and parts displayed as units may or may not be physical units, may be located in one position, or may be distributed on a plurality of network elements. Some or all of the units may be selected based on actual requirements to achieve the objectives of the solutions of the embodiments.

In addition, the functional units in the embodiments of this application may be integrated into one processing unit, or each of the units may exist alone physically, or two or more units may be integrated into one unit. The integrated unit may be implemented in a form of hardware, or may be implemented in a form of a software functional unit.

When the integrated module or unit is implemented in the form of a software functional unit and sold or used as an independent product, the integrated module or unit may be stored in a computer-readable storage medium. Based on such understanding, some or all of the processes for implementing the methods in the embodiments of this application may be completed by related hardware instructed by a computer program. The computer program may be stored in a computer-readable storage medium. When the computer program is executed by the processor, the steps of the foregoing method embodiments are implemented. The computer program includes computer program code, and the computer program code may be in a form of source code, object code, or an executable file, some intermediate forms, or the like. The computer-readable medium may include: any entity or apparatus capable of carrying the computer program code, a recording medium, a USB flash drive, a removable hard disk, a magnetic disk, an optical disc, a computer memory, a read-only memory (ROM, Read-Only Memory), a random access memory (RAM, Random Access Memory), an electrical carrier signal, a telecommunications signal, a software distribution medium, or the like. It should be noted that the content included in the computer-readable medium may be appropriately added or deleted according to requirements of legislation and patent practice in a jurisdiction. For example, in some jurisdictions, according to legislation and patent practice, the computer-readable medium does not include an electrical carrier signal or a telecommunication signal.

The foregoing embodiments are merely intended to describe the technical solutions of this application, but not to limit this application. Although this application is described in detail with reference to the foregoing embodiments, persons of ordinary skill in the art should understand that they may still make modifications to the technical solutions described in the foregoing embodiments or make equivalent replacements to some technical features thereof, without departing from the spirit and scope of the technical solutions of the embodiments of this application.

What is claimed is:

1. A multi-sensor-based state estimation method, comprising:
in each state estimation cycle, using an earliest timestamp among timestamps of one or more unused sensor messages in one or more sensor message queues as an initial timestamp, extracting, from the one or more sensor message queues, one or more sensor messages whose timestamps are later than or equal to the initial timestamp, and arranging the one or more sensor messages into a data update queue according to a sequence of timestamps, wherein a sensor message queue is used to receive a sensor message collected by a sensor participating in state estimation;
deleting a system state estimation value with a timestamp later than the initial timestamp from a state estimation queue, wherein the state estimation queue is used to store a system state estimation value predicted or updated according to the sensor message;
sequentially extracting the one or more sensor messages from the data update queue, wherein the one or more sensor messages include prediction data and update data;
using a timestamp of one of the extracted one or more sensor messages as a first timestamp;
when an extracted sensor message is prediction data, according to a Kalman filter prediction algorithm, predicting a system state estimation value corresponding to the first timestamp by using a last system state estimation value in the state estimation queue and the extracted sensor message;
when an extracted sensor message is update data, obtaining a system state estimation value corresponding to the first timestamp, and updating the system state estimation value corresponding to the first timestamp by using the extracted sensor message according to a Kalman filter update algorithm to obtain a new system state estimation value corresponding to the first timestamp;
after all of the one or more sensor messages in the data update queue are used to predict or update the system state estimation value in the state estimation queue, proceeding to a next state estimation cycle; and
detecting a system state estimation value with the latest timestamp in the state estimation queue at a predetermined frequency, and outputting the detected system state estimation value.

2. The multi-sensor-based state estimation method according to claim 1, wherein, when the extracted sensor message is update data, the obtaining a system state estimation value corresponding to the first timestamp, and updating the system state estimation value corresponding to the first timestamp by using the extracted sensor message according to Kalman filter update algorithm to obtain a new system state estimation value corresponding to the first timestamp comprises:
when the extracted sensor message is update data, determining whether there is a system state estimation value corresponding to the first timestamp; and
when there is a system state estimation value corresponding to the first timestamp, updating the system state estimation value corresponding to the first timestamp by using the extracted sensor message according to the Kalman filter update algorithm to obtain the new system state estimation value corresponding to the first timestamp.

3. The multi-sensor-based state estimation method according to claim 2, wherein, when the extracted sensor message is update data, the obtaining a system state estimation value corresponding to the first timestamp, and updating the system state estimation value corresponding to the first timestamp by using the extracted sensor message according to Kalman filter update algorithm to obtain a new system state estimation value corresponding to the first timestamp further comprises:
when there is no system state estimation value corresponding to the first timestamp, performing interpolation calculation according to the last system state estimation value in the state estimation queue to obtain the system state estimation value corresponding to the first timestamp, and updating the system state estimation value corresponding to the first timestamp by using the extracted sensor message according to Kalman filter update algorithm to obtain the new system state estimation value corresponding to the first timestamp.

4. The multi-sensor-based state estimation method according to claim 1, further comprising:
deleting a sensor message whose retention duration is greater than a predetermined duration.

5. The multi-sensor-based state estimation method according to claim 1, wherein, in each state estimation cycle, prior to the performance of using an earliest timestamp among timestamps of one or more unused sensor messages in one or more sensor message queues as an initial timestamp, extracting, from the one or more sensor message queues, one or more sensor messages whose timestamps are later than or equal to the initial timestamp, and arranging the one or more sensor messages into a data update queue according to a sequence of timestamps, wherein a sensor message queue is used to receive a sensor message collected by a sensor participating in state estimation, the method further comprises:
setting a predetermined number of sensor message queues, wherein the predetermined number is the number of sensors participating in the Kalman filtering, and one sensor message queue corresponds to one sensor participating in the Kalman filtering.

6. The multi-sensor-based state estimation method according to claim 1, wherein one or more sensors participating in state estimation comprise at least one of an update sensor and a prediction sensor.

7. A multi-sensor-based state estimation apparatus, comprising:
a queue update module, configured to, in each state estimation cycle, use an earliest timestamp among timestamps of one or more unused sensor messages in one or more sensor message queues as an initial timestamp, to extract, from the one or more sensor message queues, one or more sensor messages whose timestamps are later than or equal to the initial timestamp, and to arrange the one or more sensor messages into a data update queue according to a sequence of timestamps, wherein a sensor message queue is used to receive a sensor message collected by a sensor participating in state estimation;
a state deletion module, configured to delete a system state estimation value with a timestamp later than the initial timestamp from a state estimation queue, wherein the state estimation queue is used to store a system state estimation value predicted or updated according to the sensor message;
a data extraction module, configured to sequentially extract the one or more sensor messages from the data update queue, wherein the one or more sensor messages include prediction data and update data, and to use a timestamp of the extracted one or more sensor messages as a first timestamp;
a state prediction module, configured to, when an extracted sensor message is prediction data, according to a Kalman filter prediction algorithm, predict a system state estimation value corresponding to the first timestamp by using a last system state estimation value in the state estimation queue and the extracted sensor message;
a state update module, configured to, when an extracted sensor message is update data, obtain a system state estimation value corresponding to the first timestamp, and to update the system state estimation value corresponding to the first timestamp by using the extracted sensor message according to a Kalman filter update algorithm to obtain a new system state estimation value corresponding to the first timestamp;
a state cycling module, configured to, after all of the one or more sensor messages in the data update queue are used to predict or update the system state estimation value in the state estimation queue, proceed to a next state estimation cycle; and
a state output module, configured to detect a system state estimation value with the latest timestamp in the state estimation queue at a predetermined frequency, and to output the detected system state estimation value.

8. The multi-sensor-based state estimation apparatus according to claim 7, wherein the state update module specifically comprises:
a state determining submodule, configured to, when the extracted sensor message is update data, determine whether there is a system state estimation value corresponding to the first timestamp; and
a first update submodule, configured to, when there is a system state estimation value corresponding to the first timestamp, update the system state estimation value corresponding to the first timestamp by using the extracted sensor message according to the Kalman filter update algorithm to obtain the new system state estimation value corresponding to the first timestamp.

9. A terminal device, comprising a memory, a processor, and a computer program stored in the memory and capable of running on the processor, wherein when the processor executes the computer program, wherein the computer program, when executed by the processor, causes the processor to perform operations comprising:
in each state estimation cycle, using an earliest timestamp among timestamps of one or more unused sensor messages in one or more sensor message queues as an initial timestamp, extracting, from the one or more sensor message queues, one or more sensor messages whose timestamps are later than or equal to the initial timestamp, and arranging the one or more sensor messages into a data update queue according to a sequence of timestamps, wherein a sensor message queue is used to receive a sensor message collected by a sensor participating in state estimation;
deleting a system state estimation value with a timestamp later than the initial timestamp from a state estimation queue, wherein the state estimation queue is used to store a system state estimation value predicted or updated according to the sensor message; sequentially extracting the one or more sensor messages from the data update queue, wherein the one or more sensor messages include prediction data and update data;
using a timestamp of one of the extracted one or more sensor messages as a first timestamp;
when an extracted sensor message is prediction data, according to a Kalman filter prediction algorithm, predicting a system state estimation value corresponding to the first timestamp by using a last system state estimation value in the state estimation queue and the extracted sensor message;
when an extracted sensor message is update data, obtaining a system state estimation value corresponding to the first timestamp, and updating the system state estimation value corresponding to the first timestamp by using the extracted sensor message according to a Kalman filter update algorithm to obtain a new system state estimation value corresponding to the first timestamp;
after all of the one or more sensor messages in the data update queue are used to predict or update the system state estimation value in the state estimation queue, proceeding to a next state estimation cycle; and
detecting a system state estimation value with the latest timestamp in the state estimation queue at a predetermined frequency, and outputting the detected system state estimation value.

10. The terminal device according to claim 9, wherein, when the extracted sensor message is update data, the obtaining a system state estimation value corresponding to the first timestamp, and updating the system state estimation value corresponding to the first timestamp by using the extracted sensor message according to Kalman filter update algorithm to obtain a new system state estimation value corresponding to the first timestamp comprises:
when the extracted sensor message is update data, determining whether there is a system state estimation value corresponding to the first timestamp; and
when there is a system state estimation value corresponding to the first timestamp, updating the system state estimation value corresponding to the first timestamp by using the extracted sensor message according to the Kalman filter update algorithm to obtain the new system state estimation value corresponding to the first timestamp.

11. The terminal device according to claim 10, wherein, when the extracted sensor message is update data, the obtaining a system state estimation value corresponding to the first timestamp, and updating the system state estimation value corresponding to the first timestamp by using the extracted sensor message according to Kalman filter update algorithm to obtain a new system state estimation value corresponding to the first timestamp further comprises:
when there is no system state estimation value corresponding to the first timestamp, performing interpolation calculation according to the last system state estimation value in the state estimation queue to obtain the system state estimation value corresponding to the first timestamp, and updating the system state estimation value corresponding to the first timestamp by using the extracted sensor message according to Kalman filter update algorithm to obtain the new system state estimation value corresponding to the first timestamp.

12. The terminal device according to claim 9, wherein the computer program, when executed by the processor, causes the processor to perform operations further comprising:
deleting a sensor message whose retention duration is greater than a predetermined duration.

13. The terminal device according to claim 9, wherein, in each state estimation cycle, prior to the operation of using an earliest timestamp among timestamps of one or more unused sensor messages in one or more sensor message queues as an initial timestamp, extracting, from the one or more sensor message queues, one or more sensor messages whose timestamps are later than or equal to the initial timestamp, and arranging the one or more sensor messages into a data update queue according to a sequence of timestamps, wherein a sensor message queue is used to receive a sensor message collected by a sensor participating in state estimation, the computer program, when executed by the processor, causes the processor to perform operations further comprising:
setting a predetermined number of sensor message queues, wherein the predetermined number is the number of sensors participating in the Kalman filtering, and one sensor message queue corresponds to one sensor participating in the Kalman filtering.

14. The terminal device according to claim 9, wherein one or more sensors participating in state estimation comprise at least one of an update sensor and a prediction sensor.
